(19) United States
(12) Patent Application Publication
(10) Pub. No.: US 2017/0148955 A1
(43) Pub. Date: May 25, 2017

(54) Method of wafer level packaging of a module

(71) Applicant: CYNTEC CO., LTD., Hsinchu (TW)

(72) Inventor: Ming-Che Wu, Hsinchu (TW)

(21) Appl. No.: 14/948,366

(22) Filed: Nov. 22, 2015

(51) Int. Cl. H01L 33/48; H01L 21/768; H01L 21/683; H01S 5/022; H01L 31/02; H01L 31/0203; H01L 31/18; H01L 21/48; H01L 33/62

(52) U.S. Cl. CPC H01L 33/483; H01L 21/486; H01L 21/4853; H01L 21/76898; H01L 21/6835; H01L 33/62; H01L 31/02005; H01L 31/0203; H01L 31/1876; H01S 5/02236; H01L 2221/68327; H01L 2221/68381; H01L 2933/0033; H01L 2933/0066

(57) ABSTRACT

The method of a wafer level packaging includes preparing a substrate, assembling a system on a first side of the substrate, and placing solder balls on a second side of the substrate. The soldering balls s fixed on to the second side of the substrate after the module has been assembled.

### BACKGROUND OF THE INVENTION

1. Field of the Invention

The present invention relates to a method of a module packaging, and more particularly, a method of wafer level packaging of a module using ball placement to form solder balls on one side of a substrate.

2. Description of the Prior Art

Advancements are being made to silicon photonics due to its promise of delivering high performance optical components built in silicon module technologies. Silicon photonic is the study and application of photonic systems that use silicon as an optical medium. The silicon is patterned with sub-micrometer precision into silicon photonic structures. The silicon typically lies on top of a layer of a silicon substrate.

At present, the manufacturing of silicon photonics still presents a problem in cost and accuracy. When attaching devices to the substrate is performed before bumping is performed, the heat from the bumping process would be too high and cause the attached devices to detach from the substrate. Furthermore, the total thickness of the devices, the lid protecting the devices, and the substrate is too thick for the machinery used in the bumping process to handle. Adjustment of a pre-existing machinery to accommodate the total thickness of the devices, the lid protecting the devices, and the substrate will generate a high manufacturing cost. When bumping is performed before attaching devices to the substrate, it is hard to find a material used to protect the solder balls during bumping when the devices are being attached to the substrate. Thus, there is a need for a method for silicon photonic wafer level packaging that is accessible and cost effective.

### SUMMARY OF THE INVENTION

An embodiment of the present invention presents a method of a wafer level packaging of a module. The method comprises preparing a substrate, disposing an element on a first side of the substrate, and placing solder balls on a second side of the substrate the module is built.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a structure of a module in each step of a wafer level packaging of a module according to an embodiment of the present invention.

FIG. 2 illustrates a flowchart of a method of the wafer level packaging of the module according to FIG.1.

FIG. 3 illustrates a flowchart of a method of preparing the substrate in FIG.2.

FIG. 4 illustrates a flowchart of a method of disposing an optoelectronic element or photonic element on the substrate in FIG.2.

FIG. 5 illustrates a top view of an exemplary module formed using the wafer level packaging of the module in FIG.1

FIG. 6 illustrates a plurality of modules on a wafer substrate according to an embodiment of the present invention.

### DETAILED DESCRIPTION

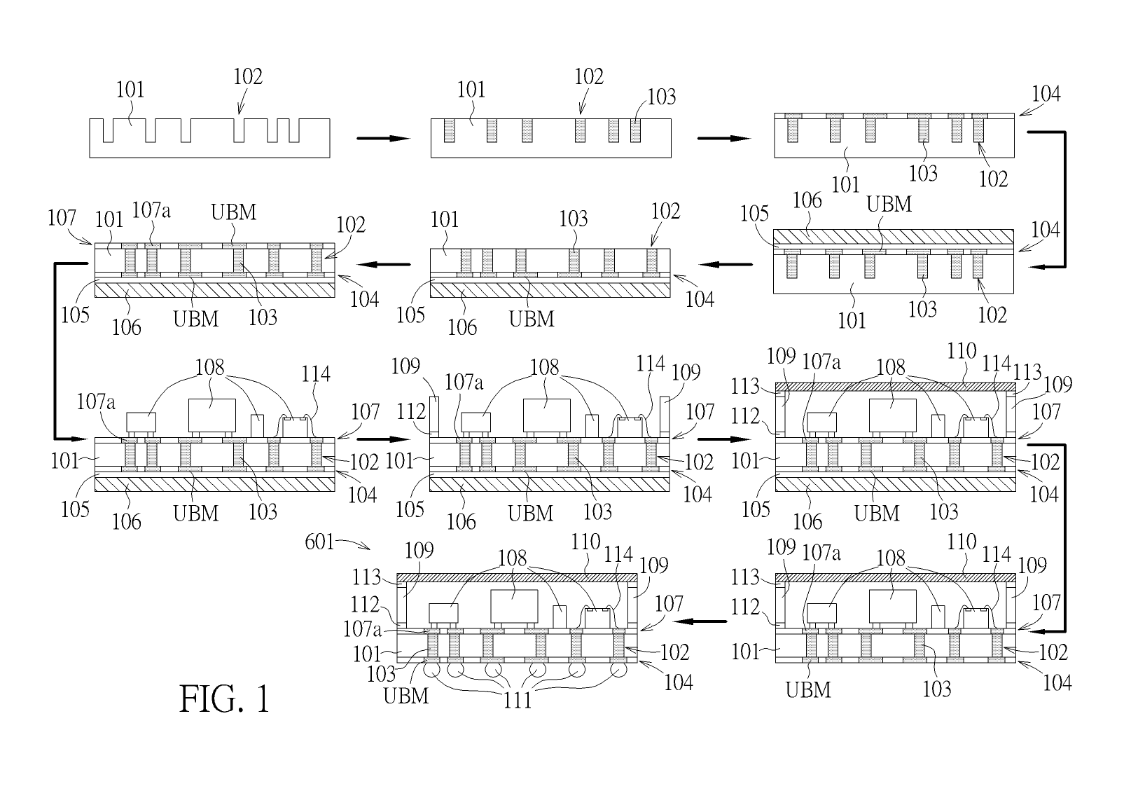

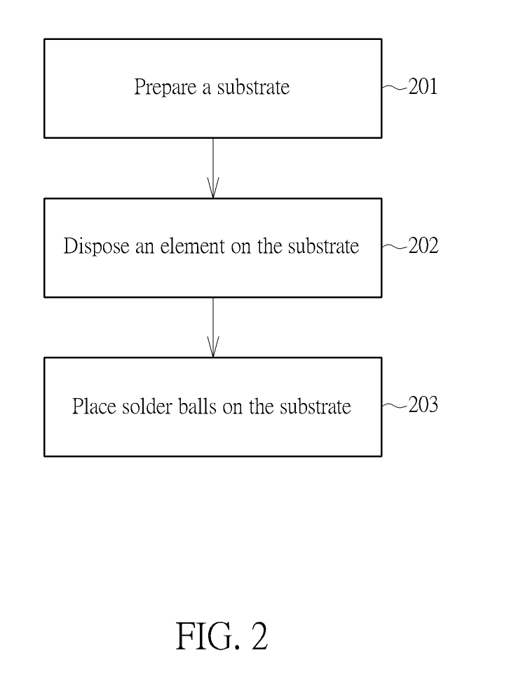

FIG. 1 illustrates a structure of a module in each step of a wafer level packaging of the module according to an embodiment of the present invention. FIG.2 illustrates a flowchart of a method of the wafer level packaging of the module according to FIG. 1. The method may include, but is not limited, to the following steps:

Step 201: prepare a substrate 101;

Step 202: dispose an optoelectronic element or photonic element such as silicon photonic on a first side of the substrate 101; and

Step 203: place solder balls on a second side of the substrate.

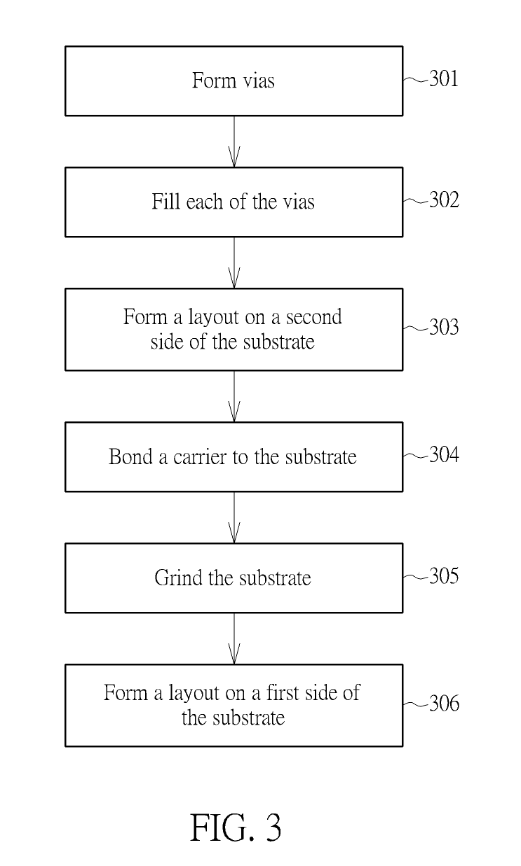

In step 201, the substrate 101 may be prepared for further use in the wafer level packaging of the module. The substrate may be a silicon wafer or a glass wafer. FIG. 3 illustrates a flowchart of a method of preparing the substrate in FIG. 2. FIG. 1 includes illustrations of structures of a module when performing step 201 of the wafer level packaging of the module in FIG. 2. The method may include, but is not limited to the following steps:

Step 301: etch the substrate to form vias (holes) 102;

Step 302: fill each of the vias 102 with a conductive material 103;

Step 303: form a layout 104 on the second side of the substrate 101;

Step 304: bond a carrier 106 to the second side of the substrate 101;

Step 305: grind the first side of the substrate 101 to reduce the thickness of the substrate 101; and

Step 306: form a layout 107 on the first side of the substrate 101.

Note that the method may not be limited to having all the above mentioned steps. In some other embodiments some of the steps included in FIG. 3 may not be included in performing step 201. In some embodiments of the present invention, at least one of steps 303 and 306 may be removed corresponding to the area of the vias 102.

In step 301, the substrate 101 maybe etched to form vias 102. The vias 102 formed during etching maybe hollow structure of buried hole having a height of approximately 100 um to 300 um. In some other embodiments, the etching process may be performed using dry etching or excimer laser. Each of the vias 102 formed may have a diameter according to the technology being used or as required by the element (or the substrate) such as optoelectronic element or photonic element being disposed. As an example the diameter of the vias 102 may be greater than or equal to 10 um.

In step 302, each of the vias 102 may be filled with a conductive material 103 to form solid structure of buried vias. The conductive material 103 may be a metal such as copper or aluminum. The conductive material 103 may be used to form interposers between the layout 104 of the second side of the substrate 101 and the layout 107 of the first side of the substrate 101. The interposers are used to couple pads on the layout 107 formed on the first side of the substrate 101 to corresponding pads on the layout 104 formed on the second side of the substrate 101 (as shown in FIG. 1).

In some other embodiments, substrate 101 only has vertical vias. The pads wherein the elements are to be coupled to are disposed directly above the vertical vias. The layout 104 and the layout 107 may no longer be formed.

In step 303, the layout 104 may be formed on the second side of the substrate 101. The layout 104 may comprise pads, traces, a redistribution layer (RDL), and/or an under bump metallization (UBM) layer. The redistribution layer may be an extra layer of wiring on first side or second side of substrate of a module that enables signal paths of the element on the substrate to be rerouted according to the need of the module. Thus, module to module bonding is made simpler. The redistribution layer may be a copper layer or aluminum. The under bump metallization layer may be formed on the redistribution layer to prevent diffusion and allow solder wetting.

In some other embodiments, when the diameter of the vias have enough area to be pads and the optoelectronic element. The first side of the vias 102 may be used for wire bonding of elements and the second side of the vias 102 may be used to place the solder balls. In this case the steps 303 and 306 may no longer be performed.

In step 304, the carrier 106 may be bonded to the second side of the substrate 101. The carrier may be a glass wafer or a silicon wafer. A carrier having a coefficient of thermal expansion (CTE) match with Silicon wafer may be preferred. The carrier may be bonded to the second side of the substrate 101 using a binding substance 105. The binding substance 105 may be a polymer material, an epoxy material, or photo resistant material (PR) material. To bond the carrier 106 to the substrate101, the binding substance 105 may be applied between the carrier 106 and the substrate 101. The binding substance 105 may be made pliable by reducing adhesion or de-adhesion of the binding substance 105 using heat or ultraviolet rays.

In step 305, the first side of the substrate 101 maybe ground or etched to reduce the thickness of the substrate 101. The first side of the substrate 101 may be ground until a surface of the vias 102 or the conductive material 103 is reached to change from buried vias to through vias. The substrate 101 may originally have a height of approximately 700 um and may be reduced to have a height of approximately 100 um to 300 um.

In step 306, a layout 107 may be formed on the first side of the substrate 101. The layout 107 may be used to form conductive tracks, pads and other features used to couple elements 108 on the substrate 101. The conductive tracks may be formed using conductive materials such as copper or aluminum.

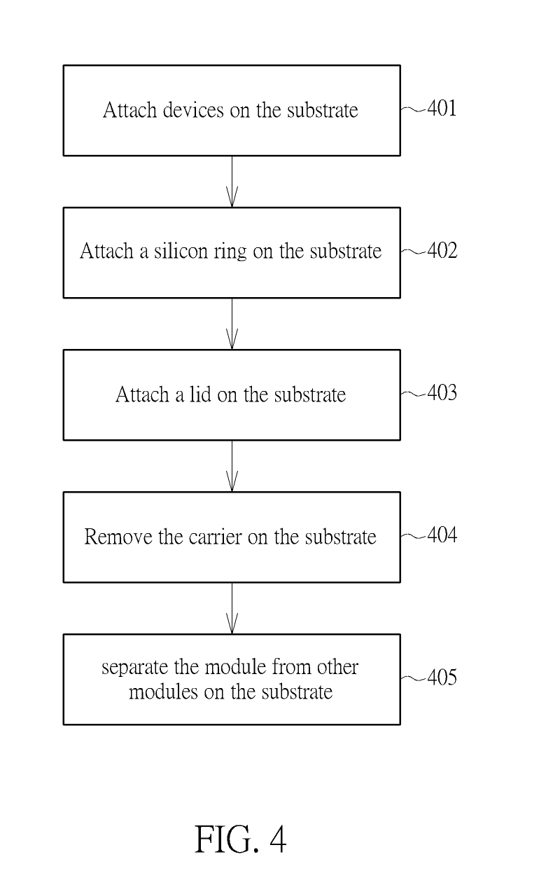

In step 202, at least one optoelectronic element or photonic element such as silicon photonic may be disposed on the first side of the substrate 101. Optoelectronic element or photonic element such as silicon photonic used to process optical signals. The process may include the conversion of an electronic signal to an optical signal, and modulation, condensing, splitting, guiding, collimating, filtering, optical coupling, etc. of optical signals. The elements used for transmitting the optical signal may include a laser diode, alight emitting diode. Such elements maybe surface emitting or edge emitting. The optical signal may be detected using a photo-detector that may be a photo diode. Example of the photo diode may be a p-n diode, a p-i-n diode, or an avalanche photo diode. Another way of detecting optical signals is using a Metal-Semiconductor-Metal (MSM) photo-detector or a photoconductor. Modulation, condensing, splitting, guiding, collimating, filtering, optical coupling, etc. of optical signals may be performed using a photonics IC, a condenser lens, an optical splitter, a waveguide, an optical isolator, etc. The abovementioned optoelectronic elements may be disposed to the substrate 101 using a soldering method. A plurality of elements of plural modules may be disposed on one substrate 101 in a single wafer level packaging process. The module may include the ring 109, the lid 110, and a circuit. The circuit of the module may be built using a combination of elements 108 active and/or passive electronic components such as a flip chip (package), a bare die, a ball grid array integrated circuit(IC), a laser diode, etc. FIG. 4 illustrates a flowchart of a method of disposing the optoelectronic element or photonic element on the substrate in FIG. 2. FIG. 1 includes illustrations of structures of the module when performing step 202 of the wafer level packaging of the module in FIG. 2. The method may include, but is not limited to the following steps:

Step 401: attach elements 108(including at least one optoelectronic element or photonic element) on the first side of the substrate 101;

Step 402: attach a ring 109 on the first side of the substrate 101;

Step 403: attach a lid 110 on the first side of the substrate 101;

Step 404: remove the carrier 106 on the second side of the substrate 101; and

Step 405: separate the module from other modules on the substrate 101. Note that the step 405 may be included in step 202 but could easily be performed after step 203. The inclusion of step 405 in step 202 is only an exemplary embodiment and should not be taken as a limitation of the sequence for which step 405 is to be performed.

In step 401, elements 108 may be attached on the first side of the substrate 101. The said elements 108 may be electronic components for silicon photonics, of which may include, but is not limited to, an electric integrated circuit, a photonic integrated circuit, a laser diode (LD), and a laser diode lens. When electronic components for silicon photonics are being attached to the substrate 101, the electric integrated circuit, the photonic integrated circuit, and the laser diode may be positioned and attached first before the laser diode lens is attached to ensure the alignment of the laser diode lens. The elements 108 may have pin pads that may be used to electrically couple the elements 108 to the pads 107a of the layout 107 of the first side of the substrate 101. The coupling of the pin pads of the elements 108 on to the pads 107a of the layout 107 may be done through soldering or through wire bonding. The soldering material for coupling the elements 18 to the pads of the layout 107 maybe conductive alloy materials such as tin-gold (SnAu), tin-silver alloy (SnAg), tin-silver-copper alloy (SnAgCu), etc. The conductive alloy materials may have a melting point ranging from 280° C. to 340° C. The wire bonding method may use bonding wires 114 made of conductive materials such as copper, gold, and silver to couple the pin pads of the elements 108 on to the pads of the layout 107.

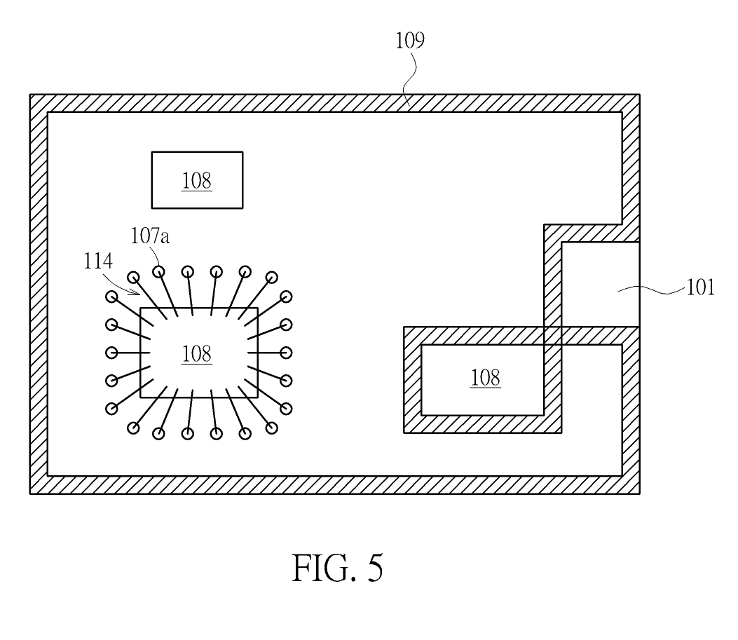

In step 402, the ring 109 may be attached on the first side of the substrate 101. The ring 109 may be translucent or an optical medium such as material made of glass or silicon. Light can pass through the ring 109 so that optical elements on the substrate 101 within the ring 109 can receive or transmit a light signal. The ring 109 maybe placed to surround at least one element 108 and/or surround the whole circuit of the module. The size and shape of the ring 109 may depend on the size of circuit of the module being built or the device 108 to be protected. For example, when the ring 109 is used to protect an element 108 such as a laser diode, the area surrounded by the ring 109 may be greater than the dimension of the laser diode. In some other embodiments, the shape of the ring 109 may not be fixed. The shape of the ring 109 may conform to the arrangement of the elements 108 of the module on the substrate 101. In further embodiments, the ring 109 may be used to protect only a single element such as laser diode being sensitive to humidity within a module and, at the same time, the whole of the circuit of the module. FIG. 5 illustrates a top view of an exemplary module formed using the wafer level packaging of the module in FIG. 1. The ring 109 may be attached using local heating. The ring 109 may be attached to the substrate 101 using binding material 112 such as conductive alloy materials (i.e. tin-gold (SnAu), tin-silver alloy (SnAg), tin-silver-copper alloy (SnAgCu), etc.). The melting ranging of the binding substance 105 is lower than the melting ranging of the binding material 112. In this embodiment, the conductive alloy materials may have a melting point ranging from 280° C. to 340° C. Since local heating is used, the binding substance 105 such as the polymer used to attach the carrier will not be melted. The binding material 112 may not be limited to the conductive alloy materials, the conductive alloy materials is merely an example of a material that can be used to attach the ring 109 to the substrate 101.

In step 403, the lid 110 may be attached above the first side of the substrate 101 and ring 109. The lid 110 is attached to the first side of the substrate 101 through the ring 109. There is a plurality of methods of which the lid 110 may be attached to the ring 109. The attachment 113 that is an intermediate layer between the lid 110 and the ring 109 must be hermetically sealed to prevent outside environment from interrupting or damaging the operation of the module. The lid 110 may be attached to the ring 109 through direct bonding. In direct bonding, the bonding process is done without any additional intermediate layers. Anodic bonding may also be used to attach the lid 110 to the ring 109. Anodic bonding is a wafer bonding process used to seal glass to either silicon or metal without introducing an intermediate layer. Thus, when the ring 109 and the lid 110 are both made of silicon, anodic bonding performs silicon to silicon bonding. Eutectic bonding may also be used to attach the lid 110 to the ring 109. Eutectic bonding is a bonding process that uses a eutectic metal layer to bond the lid 110 to the ring 109. The eutectic metals are alloys that transform directly from solid to liquid state, or vice versa, from liquid to solid state, at a specific composition and temperature without passing a two-phase equilibrium. The eutectic metals (conductive alloy metals) may, for example, be tin-gold (SnAu), copper-tin (CuSn), gold-silicon (AuSi), aluminum-silicon (AlSi), tin-silver-copper alloy (SnAgCu), etc. Adhesive bonding may also be used to attach the lid 110 to the ring 109. Adhesive bonding is a bonding process that uses the application of an intermediate layer to attach the lid 110 to the ring 109. The intermediate layer may be an adhesive that is organic or inorganic and may be deposited on one or both the lid 110 and the ring 109. The intermediate layer may, for example, be SU-8 polymerizes, benzocyclobutene (BCB), etc. Glass frit bonding may also be used to attach the lid 110 to the ring 109. Glass frit bonding is a bonding process that uses an intermediate glass layer. Having low viscosity would allow the intermediate glass layer be applied to rough or irregular surfaces and ensure a hermetically sealed enclosure between the lid 110 and the ring 109. Furthermore, the lid 110 may be attached to the ring 109 using a conductive material. The conductive material used to attach the lid 110 to the ring 109 may, for example, be gold or silver. The lid 110 may be used to protect the elements 108 from outside environment, such as humidity that may affect, for example, the laser diode. For example, the lid 110 may be used to protect elements 108 such as the laser diode and bonding wires 114 of the elements as shown in FIG. 5. The lid 110 may be made of glass or silicon. The total height of the ring 109 and the lid 110 may be approximately 800 um to 1000 um. Furthermore, the outer layer of the lid 110 may be coated with an anti-reflection coating. For silicon photonics, the anti-reflection coating prevents dissipation of energy from the signal transmitted by the laser diode. The process of attaching the lid 110 may be done in an environment with low pressure and high nitrogen.

Furthermore, in some other embodiments of the present invention, the ring 109 and the lid 110 may be built as one body. For example, the lid 110 may be etched to a recess on the lid 110 having a depth able to enclose at least one of the elements 108 or the whole circuit of the module. Thus, there is no need to attach the ring 109 and the lid 110 to each other. In this way, the quality of the hermetically sealed enclosure to protect the module is greatly increased. The step 402 and step 403 are combined to step 4023 that the body including the ring 109 and the lid 110 is attached on the first side of the substrate 101.

In step 404, the carrier 106 on the second side of the substrate 101 may be removed. The carrier 106 may be removed using a laser, ultraviolet ray (de-adhesion or reducing adhesiveness of the binding substance 105), heating or by mechanical means. And, the second side of the substrate 101 may be cleaned for the next step in the wafer level packaging process of module.

In step 405, the modules on the substrate 101 may be separated from each other. This step maybe performed before or after performing step 203 of the wafer level packaging of the module in FIG. 2. During a semiconductor fabrication process, a single wafer, in this case a substrate 101 may include a plurality of modules. After all of the modules on the substrate 101 have been built, the modules may be separated from each other through dicing. The number of modules built in one wafer may be dependent on the size of the wafer and the area needed to build the module and form a ring around the module.

Before the solder balls 111 are placed on the substrate 101, the thickness of the module may be greater than or equal to 800 um. The currently available method and machinery to perform bumping on a module having thickness approximately 1000 um is not readily available. To overcome the above mentioned problem, in step 203, the solder balls 111 may be placed on a second side of the substrate 101. FIG. 1 further includes an illustration of a structure of the module after performing step 203 of the wafer level packaging of the module in FIG. 2.

The method of placing solder balls on the second side of the substrate 101 may be referred to as ball placement. Ball placement uses local heating to attach each of the solder balls 111 on the substrate 101. The ball placement may use a laser or ultra violet for curing the solder balls 111 in place. The present invention is not limited to having each of the solder balls placed on the second substrate one at a time. One or more solder balls may be aligned to corresponding coordinates of the second substrate at a time and local heating and a mask on the coordinates is used to attach the plurality of solder balls on to the substrate.

During ball placement, a solder ball 111 may be placed on a specific coordinate of the substrate 101. In some embodiments, the solder ball 111 may be placed on top of an under bump metallization (UBM) layer on the substrate 101. After the solder ball has been aligned to a specific coordinate of the substrate 101, a local heat will be applied to the specific coordinate. And, the solder ball 111 may be attached onto the substrate 101. The above mentioned process maybe repeated until all of the solder balls 111 required are attached to the under bump metallization (UBM) of the substrate 101.

Depending on the ball size and pitch, bumping process may use screen printing to form the solder balls. The screen printing process needs to apply pressure onto the module when being performed. When the module shown in the second to the last structure of the module in FIG. 1 is turned over to have the second side of the substrate 101 to face up, the module is supported by the by the ring 109.

In the instant embodiment, since the ball placement uses local heating to attach each solder ball 111, less pressure is applied to the module. Thus, the wobble is substantially decreased and the alignment of solder balls 111 corresponding to the substrate 101 is more accurate. The solder balls 111 may be formed using conductive alloy materials such as tin-silver alloy (SnAg), tin-silver-copper alloy (SnAgCu), silver, or tin. The placement of the balls may be performed on the whole wafer including a plurality of modules or performed on each module after being cut from the whole wafer. The solder balls 111 may have a size (i.e. area and height) that is dependent on the size of the under bump metallization (UBM) of the corresponding fabrication technology. In some exemplary embodiment, the solder balls 111 may have a height from the substrate 101 of greater than or equal to 50 um.

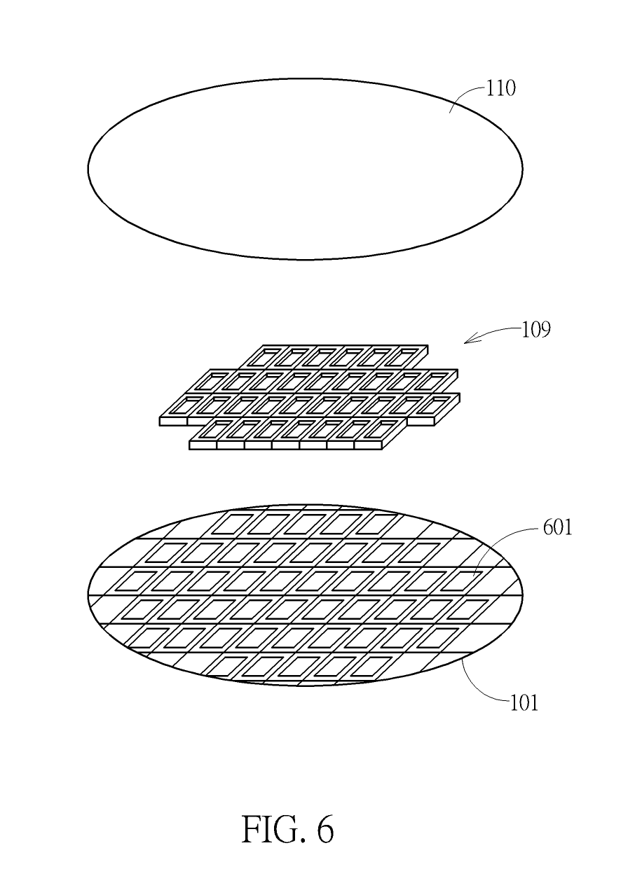

FIG. 6 illustrates a plurality of modules on a wafer substrate according to an embodiment of the present invention. As shown in FIG. 6, a plurality of modules 601 may be built on a single wafer substrate. The plurality of modules may be the same to each other. The wafer substrate is the substrate 101 shown in FIG. 1. The substrate 101 may be a silicon wafer or a glass wafer. Wafer substrates are available in a variety of diameters from 25.4 mm (1 inch) to 300 mm (11.8 inches). As the diameter of the wafer substrate increase, the number of modules 601 that may be produced at a single wafer substrate may also be increased. In order to minimize the cost per module, the number of modules to be made from a single wafer substrate may be maximized. The modules may have a square or rectangular shape due to the constraint of wafer dicing. Wafer dicing is the process of separating the plurality of modules 601 from each other. After preparing the substrate 101 to include pads and tracks for the circuit of the module, the elements to build the circuit of the modules may be placed on the substrate 101 using soldering method or wire bonding method. After the circuit of the plurality of modules 601 is formed, a ring 109 may be formed for each of the plurality of modules 601. The lid 110 may then be placed on top of the plurality of rings 109. The lid may be a single wafer such as the substrate 101. The lid 110 may have the same size as the substrate 101. The lid 110, the rings 109, and the substrate 101 may be made of the same material or different materials. The materials used to form the lid 110, the rings 109, and the substrate 101 may be silicon or glass.

The wafer level packaging of the module presented is not limited to being used for silicon photonics module. The wafer level packaging of the module may also be used on wireless modules, logic system modules, sensor modules, etc. The conductive materials used to form the above mentioned conductive tracks, the redistribution layer, the under bump metallization layer, and metal fillings for the vias are not limited to using copper or aluminum. Other conductive materials having greater melting point that the solder balls may be used to form the above mentioned conductive tracks, the redistribution layer, the under bump metallization layer, and metal fillings for the vias. Since the machineries used in the method of the wafer level packaging presented are matured, the cost for manufacturing silicon photonics module using the method of the wafer level packaging of a module is greatly reduced.

Those skilled in the art will readily observe that numerous modifications and alterations of the device and method may be made while retaining the teachings of the invention. Accordingly, the above disclosure should be construed as limited only by the metes and bounds of the appended claims.

1. A method of a wafer level packaging of a module, comprising:
a step of preparing a substrate;
a step of attaching a carrier on a second side of the substrate;
a step of attaching at least one element on a first side of the substrate after the carrier is attached;
a step of attaching a ring and a lid on the first side of the substrate after the at least one element is attached;
a step of removing the carrier on the second side of the substrate after the ring and lid are attached;
and
a step of placing solder balls on a second side of the substrate after the carrier has been removed.

2. The method of claim 1, wherein the substrate is a glass wafer or a silicon wafer.

3. The method of claim 1, wherein the step of preparing the substrate comprises:
etching the substrate to form vias;
filling each of the vias with a conductive material;
bonding a carrier to the second side of the substrate;
grinding the first side of the substrate to reduce the thickness of the substrate.

4. The method of claim 3, wherein the carrier is a glass wafer or a silicon wafer.

5. The method of claim 3, wherein the step of preparing the substrate comprises forming a layout on the second side of the substrate.

6. The method of claim 3, wherein the step of preparing the substrate comprises forming a layout on the first side of the substrate.

7. The method of claim 3, wherein the lid is a glass wafer or a silicon wafer.

8. The method of claim 3, wherein a polymer is used to bond the carrier to the second side of the substrate.

9. The method of claim 3, wherein a layout on the second side of the substrate comprises pads, a redistribution layer (RDL) and/or an under bump metallization (UBM) layer.

10. The method of claim 1, wherein the ring comprises translucent or optical materials so that light can pass through the ring and optical elements on the substrate within the ring can receive or transmit a light signal.

11. The method of claim 1, wherein the step of attaching a ring and a lid on the first side of the substrate comprises:
attaching the ring on the first side of the substrate; and
attaching the lid on the first side of the substrate.

12. The method of claim 1, wherein the carrier is removed from the second side of the substrate by heating, mechanical means, by using a laser or by using ultraviolet ray.

13. The method of claim 1, wherein the lid is a glass lid or a silicon lid.

14. The method of claim 1, wherein attaching the lid on the first side of the substrate is attaching the lid on the first side of the substrate using direct bonding, anodic bonding, eutectic bonding, adhesive bonding, or glass frit bonding.

15. The method of claim 1, wherein attaching the ring on the first side of the substrate is attaching the ring around at least one of the at least one element.

16. The method of claim 15, wherein attaching the ring on the first side of the substrate is attaching the ring around a laser diode of the module.

17. The method of claim 1, wherein attaching the lid on the first side of the substrate is attaching a lid having a plurality of recesses on the first side of the substrate; each of the plurality recesses having a volume large enough to enclose at least one device of the module.

18. The method of claim 1, wherein the at least one element comprises a laser diode and the step of attaching the ring and the lid on the first side of the substrate after the at least one element is attached comprises the ring surrounding the laser diode to protect the laser diode from humidity.

19. The method of claim 1, wherein the step of placing the solder balls on the second side of the substrate after the carrier has been removed is attaching the solder balls on the second side of the substrate using local heating.

20. The method of claim 1, wherein the step of placing the solder balls on the second side of the substrate, comprises:
aligning a solder ball on a coordinate of the second side of the substrate; and
applying a local heat to the coordinate of the second side of the substrate to attach the solder ball onto the second side of the substrate.

21. The method of claim 20, wherein aligning the solder ball on the coordinate of the second side of the substrate is aligning one or more solder balls on corresponding coordinates of the second side of the substrate.

22. The method of claim 1, wherein the at least one element includes an optoelectronic element ora photonic element.
